(19) United States
(12) Patent Application Publication
(10) Pub. No.: US 2022/0013336 A1
(43) Pub. Date: Jan. 13, 2022

(54) PROCESS KIT WITH PROTECTIVE CERAMIC COATINGS FOR HYDROGEN AND NH3 PLASMA APPLICATION

(71) Applicant: Applied Materials, Inc., Santa Clara, CA (US)

(72) Inventors: Jian WU, San Jose, CA (US); Lara A. HAWRYLCHAK, Gilroy, CA (US); Ren-Guan DUAN, Fremont, CA (US); Bernard L. HWANG, Santa Clara, CA (US); Malcolm J. BEVAN, Santa Clara, CA (US); Wei LIU, San Jose, CA (US)

(21) Appl. No.: 16/926,104

(22) Filed: Jul. 10, 2020

(51) Int. Cl. H01J 37/32; H01L 21/683; B08B 7/00

(52) U.S. Cl. CPC H01J 37/32495; H01L 21/6833; H01L 21/67069; H01J 37/3244; B08B 7/0035; H01J 37/32513

(57) ABSTRACT

A method and apparatus for the use of hydrogen plasma treatments is described herein. The process chamber includes a plurality of chamber components. The plurality of chamber components may be coated with a yttrium zirconium oxide composition, such as a Y₂O₃—ZrO₂ solid solution. Some of the plurality of chamber components are replaced with a bulk yttrium zirconium oxide ceramic. Yet other chamber components are replaced with similar components of different materials.

### BACKGROUND

### Field

Embodiments of the present disclosure generally relate to ceramic coated components, and a substrate processing chamber including the same.

### Description of the Related Art

In the semiconductor industry, devices are produced at an ever-decreasing size. Some manufacturing processes include plasma etch and plasma clean process to expose a substrate to a high-speed stream of plasma to etch or clean the substrate. Hydrogen plasma processes are especially useful, but are highly corrosive and may corrode components within a processing chamber. The corrosion of chamber components generates particles, which contaminate the substrate being processed and contribute to device defects.

As device geometries shrink, susceptibility to defects increases, and particle contaminant requirements become more stringent. Accordingly, as device geometries shrink, allowable levels of particle contamination may be reduced. To minimize particle contamination introduced by plasma etch and/or plasma clean processes, chamber materials have been developed that are resistant to plasmas. Examples of such plasma resistant materials include ceramics composed of Al₂O₃, AlN, SiC, Y₂O₃, quartz, and ZrO₂. Different ceramics provide different material properties, such as plasma resistance, rigidity, flexural strength, thermal shock resistance, and so on. Also, difference ceramics have different material costs.

The location and characteristics of different ceramic coatings or ceramic replacement components greatly influence the deposition of particles on the substrate. Accordingly, there is a need for the utilization of a combination of ceramic coatings and ceramic components which minimizes particle deposition on the substrate, while maintaining structural integrity of the chamber and reducing overall cost.

### SUMMARY

The present disclosure generally relates to an apparatus for substrate processing including a chamber body, a lower liner disposed within the chamber body, an upper liner disposed on top of the lower liner and within the chamber body, a liner door disposed through the upper liner and the chamber body, a chamber lid disposed on top of the chamber body, and a gas nozzle disposed through the chamber lid. Each of the lower liner, the upper liner, and the liner door further include a spray coated yttrium zirconium oxide layer disposed thereon and the gas nozzle is a bulk ceramic gas nozzle.

Another embodiment of an apparatus for substrate processing includes a chamber body, a lower liner disposed within the chamber body, an upper liner disposed on top of the lower liner and within the chamber body, a liner door disposed through the upper liner and the chamber body, a chamber lid disposed on top of the upper liner, a gas nozzle disposed through the chamber lid, and one or more nickel plated or stainless steel gaskets disposed between the lower liner and the upper liner, the upper liner and the chamber lid, and the lower liner and the substrate support pedestal. The lower liner, the upper liner, and the liner door further include a spray coated yttrium zirconium oxide layer disposed thereon, wherein the yttrium zirconium oxide further comprises a Y₂O₃—ZrO₂ solid solution. The gas nozzle is a bulk ceramic gas nozzle.

Yet another embodiment of an apparatus for substrate processing includes a chamber body, a lower liner disposed within the chamber body, an upper liner disposed on top of the lower liner and within the chamber body, a liner door disposed through the upper liner and the chamber body, a chamber lid disposed on top of the upper liner, a gas nozzle disposed through the chamber lid, an induction coil disposed above the chamber lid, and a shielding electrode disposed between the induction coil and the chamber lid. Each of the lower liner, the upper liner, and the liner door further comprise a spray coated yttrium zirconium oxide layer disposed thereon. The gas nozzle is a bulk ceramic gas nozzle. The thickness of the spray coated yttrium zirconium oxide layer is about 25 microns to about 300 microns and the spray coated yttrium zirconium oxide layer is a purified yttrium zirconium oxide coating with a concentration of 99% or more Y₂O₃ and ZrO₂.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 is a schematic cross-sectional view of a process chamber assembly, according to one embodiment.

FIG. 2 is a schematic cross-sectional view of a ceramic coated chamber component.

FIG. 3 is a method of processing a substrate.

FIG. 4 is a chart illustrating substrate particle contamination levels.

FIG. 5 is a graph illustrating substrate particle contamination caused by the process chamber lid.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the disclosure provided herein include a process chamber for substrate processing. The process chamber may be utilized during hydrogen plasma treatment of a substrate. The process chamber includes a plurality of chamber components. One or more of the plurality of chamber components are coated with a yttrium zirconium oxide composition, such as a Y₂O₃—ZrO₂ solid solution. Some of the plurality of chamber components are replaced with a bulk yttrium zirconium oxide ceramic. Yet other chamber components are replaced with similar components of different materials. The coatings and component replacements are performed in order to reduce particle contamination of the substrate during substrate processing operations involving hydrogen plasma.

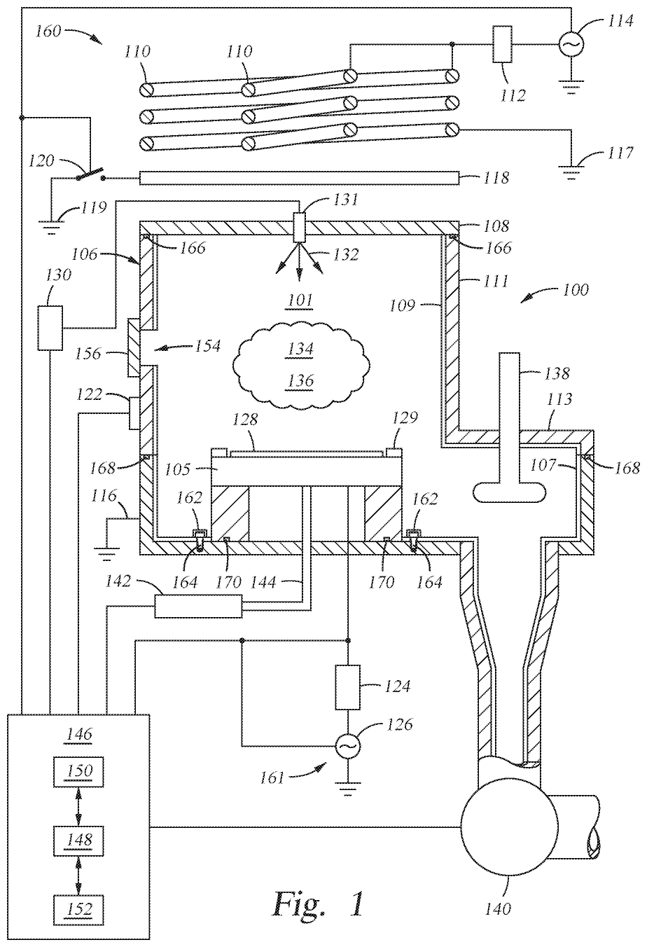

FIG. 1 is a schematic cross-sectional view of a process chamber assembly 100, according to one embodiment. As shown, the processing chamber assembly 100 includes a plasma processing chamber 101, a plasma source 160, a bias power system 161, and a controller 146. The plasma processing chamber 101 provides a chamber for the treatment of a thin film that has been formed on a surface of a substrate 128. Typically, the thin film is deposited on the surface of the substrate 128 in a separate thin film deposition chamber coupled to a shared cluster tool within the processing chamber assembly 100. In some embodiments, the plasma processing chamber 101 may also be additionally configured to deposit a thin film layer on the surface of the substrate. The plasma source 160 converts a gaseous mixture 134 (such as a hydrogen-containing gaseous mixture) to a plasma 136, which bombards the substrate 128 to alter the properties of the film grown thereon. The bias power system 161 provides a voltage bias across the substrate 128 to facilitate the treatment process. The controller 146 implements the specific process conditions for both film growth and film treatment. The entire processing chamber assembly 100 is configured to grow or process a film formed on the substrate 128 using a specific plasma process provided by use of commands provided by the controller 146. The thin film treatment processes are assisted by the plasma source 160 and the bias power system 161.

As shown, the plasma processing chamber 101 includes a chamber body 106, a chamber lid 108, a substrate support pedestal 104, an electrostatic chuck 105, an electrical ground 116, a gas panel 130, a gas nozzle 131 with entry ports 132, a throttle valve 138, a vacuum pump 140, and a gas source 142. Plasma processing chamber 101 may be any suitable plasma processing chamber, such as an inductively coupled plasma (ICP) processing chamber. In one embodiment, the processing chamber 101 and the thin film deposition chamber (not shown) are part of the same cluster tool (not shown). The cluster tool (e.g., Centura® system from Applied Materials Inc.) is configured to allow a substrate to be transferred between the thin film deposition chamber and the processing chamber 101 without being exposed to air.

As shown in FIG. 1, processing chamber 101 includes a chamber body 106, a dielectric chamber lid 108 and a substrate support pedestal 104 disposed within the chamber body 106. The chamber body 106 and dielectric chamber lid 108 help isolate the interior volume of the processing chamber 101 from the outside environment. Typically, chamber body 106 is coupled to an electrical ground 116. The chamber body 106 may also be described as the chamber walls of the processing chamber 101. The chamber body 106 includes sidewalls and a bottom wall of the processing chamber 101. The dielectric chamber lid 108 may be composed of any suitable dielectric, such as quartz. For some embodiments, dielectric chamber lid 108 may assume a different shape (e.g., dome-shaped). In some embodiments, the chamber lid 108 may be coated with a ceramic coating, as further described herein. The gas nozzle 131 with the entry ports 132 is fluidly connected to the gas panel 130 and the processing chamber 101. The gas nozzle 131 is any suitable gas nozzle and comprises a bulk ceramic. The bulk ceramic is further described below.

An opening 154 is formed through the chamber body 106. The opening 154 is sized for the transfer of a substrate to and from the processing chamber 101. The opening 154 is disposed on a sidewall of the chamber body 106. The opening 154 is a part of a valve between the process chamber assembly 100 and a cluster tool (not shown). The opening 154 may be part of a slit valve or a press and seal valve assembly. The liner door 156 of the valve disposed adjacent the opening 154 is a tin or lead material. The liner door 156 includes a ceramic liner, such as an yttrium zirconium oxide. The ceramic liner may be similar to other ceramic liners described herein.

A detector 122 is attached to chamber body 106 to facilitate determining when a gas mixture within chamber 101 has been energized into plasma. Detector 122 may, for example, detect the radiation emitted by the excited gases or use optical emission spectroscopy (OES) to measure the intensity of one or more wavelengths of light associated with the generated plasma. The entire plasma source 160 creates plasma 136 from the gaseous mixture 134 to treat the deposited thin film.

The chamber body 106 includes an upper chamber body 111 and a lower chamber body 113. The upper chamber body 111 is an upper portion of the chamber body 106, such that the upper chamber body 111 includes the opening 154, the detector 122, and the throttle valve 138 disposed therein. The upper chamber body 111 is adjacent to the chamber lid 108. The upper chamber body forms at least a portion of the processing chamber 101. The upper chamber body 111 further includes an upper liner 109 lining the inside of the upper chamber body 111.

The lower chamber body 113 is a lower portion of the chamber body 106, such that the lower chamber body 113 includes the vacuum pump 140 and the pedestal 104 disposed therein. The vacuum pump 140 is disposed at an opening within the lower chamber body 113. The pedestal 104 is disposed on top of a portion of the lower chamber body 113. The lower chamber body 113 is disposed below the upper chamber body 111. The lower chamber body 113 forms at least a portion of the processing chamber 101. The lower chamber body 113 further includes a lower liner 107 lining the inside of the upper chamber body 111.

The upper liner 109 and the lower liner 107 are disposed on the inside surfaces of the upper chamber body 111 and the lower chamber body 113 respectively. The upper liner 109 and the lower liner 107 are copper with a tin, lead, or tin and lead coating. The copper may in some embodiments be berrylium copper. The upper liner 109 and the lower line 107 further include ceramic coatings. The ceramic coatings are yttrium zirconium oxide coatings. The yttrium zirconium oxide coatings are described in greater detail herein.

In operation, a substrate 128, such as a semiconductor substrate, may be placed on the electrostatic chuck 105, and process gases may be supplied from a gas panel 130 through entry ports 132 in an effort to form a gaseous mixture 134. The substrate 128 is a bare silicon wafer, according to one embodiment. In another embodiment, the substrate 128 is a patterned silicon wafer as is typically used in logic gates, I/O gates, field effect transistors, FINFETs, or memory applications. Typical process gases that may be used in one or more of the processes described herein are described below. Gaseous mixture 134 may be energized into a plasma 136 in processing chamber 101 by applying power from the RF power source 114. The pressure within the interior of processing chamber 101 may be controlled using a throttle valve 138 and a vacuum pump 140. In some embodiments, the temperature of chamber body 106 may be controlled using liquid-containing conduits (not shown) that run through chamber body 106 or heating elements embedded in chamber body 106 (e.g., heating cartridges or coils) or wrapped around processing chamber 101 (e.g., heater wrap or tape).

The temperature of the substrate 128 may be controlled by controlling the temperature of pedestal 104. The temperature of the electrostatic chuck 105 can be controlled from a range from 20-500° C. by use of heating and cooling elements. The substrate 128 is “chucked” to the substrate supporting surface of the electrostatic chuck 105 during processing to actively control the temperature of the substrate. The temperature control of the electrostatic chuck 105 and substrate via cooling elements embedded within the pedestal 104 helps reduce unwanted increased temperature due to ion bombardment. Helium (He) gas from a gas source 142 is provided via a gas conduit 144 to channels (not shown) formed in the pedestal surface under substrate 128. The helium gas may facilitate heat transfer between pedestal 104 and substrate 128. During processing, pedestal 104 may be heated to a steady state temperature, and then the helium gas may facilitate uniform heating of the substrate 128. Pedestal 104 may be so heated by a heating element (not shown), such as a resistive heater embedded within pedestal 104, or a lamp generally aimed at pedestal 104 or substrate 128 when thereon. Using such thermal control, substrate 128 may be maintained at a first temperature between about 20-500° C. The components of the plasma source 160 provide an environment for the film growth and densification.

A plasma screen ring 129 is disposed around the outer edge of the substrate 128 and on top of the pedestal 104. The plasma screen ring 129 surrounds the substrate 128. The plasma screen ring 129 improves uniformity of processing (e.g., deposition and etch) near the edges of the substrate 128. The plasma screen ring 129 further protects the underside edges of the substrate 128. In embodiments as described herein, the plasma screen ring 129 is a bulk ceramic plasma screen ring, such that the plasma screen ring 129 is a yttrium zirconium oxide plasma screen ring or an aluminum oxide plasma screen ring 129. The plasma screen ring 129 may also be an alumina ring with a yttrium zirconium oxide coating. The yttrium zirconium oxide coating may be similar to any of the yttrium zirconium oxide coatings described herein. In some embodiments, the plasma screen ring 129 comprises two attachable/seperable plasma screen ring components, such that the two attachable plasma screen ring components engage one another to form a multi-component plasma screen ring 129. Each of the two plasma screen ring's 129 subcomponents are coated separately using any of the ceramic coatings described herein.

The pedestal 104 is connected to the lower chamber body 113 of the chamber body 106 and the lower liner 107 via one or more fasteners 164. The one or more fasteners 164 are disposed through a bottom portion of the pedestal 104, the lower chamber body 113, and the lower liner 107. The one or more fasteners 164 may be screws, bolts, or any other suitable fastener. The one or more fasteners 164 include lead and tin. In some embodiments, the one or more fasteners 164 may be copper fasteners with a lead or tin coating. A fastener cover 162 is disposed over the portion of the fastener 164 disposed within the plasma processing chamber 101. The fastener cover 162 is a bulk ceramic part, such as a yttrium zirconium oxide ceramic part. Alternatively, the fastener cover 162 may be an aluminum oxide ceramic part. The composition of the bulk ceramic fastener cover 162 is further described herein. The one or more fasteners 164 and the fastener covers 162 disposed on the fasteners 164 are disposed about the outer radius of the base of the pedestal 104. The one or more fasteners 164 connect the pedestal 104, the lower chamber body 113, and the lower liner 107 and secure the components together.

As shown, the plasma source 160 includes coil element 110, first impedance matching network 112, RF power source 114, electrical ground 117, shielding electrode 118, electrical ground 119, switch 120, and detector 122. Above a dielectric chamber lid 108, a radio frequency (RF) antenna including at least one inductive coil element 110 is disposed thereon. In one configuration, as shown in FIG. 1 two coaxial coil elements, which are disposed about a central axis of the process chamber, are driven at an RF frequency to generate the plasma 136 in the processing region of the processing chamber assembly 100. In some embodiments, inductive coil elements 110 may be disposed around at least a portion of chamber body 106. One end of inductive coil element 110 may be coupled, through a first impedance matching network 112, to an RF power source 114, and the other end may end may be connected to an electrical ground 117 as shown. Power source 114 is typically capable of producing up to 4 kilowatts (kW) at a frequency of 13.56 MHz. The RF power supplied to inductive coil elements 110 may be pulsed (i.e., switched between an on and an off state) or power cycled (i.e., varying a power input from a high level to a low level) at a frequency ranging from 1 to 100 kHz. The average ion density of the plasma 136 can be varied from 1E10 to 1E12 ions per cubic centimeter (cm⁻³). The plasma density can be measured by use of any conventional plasma diagnostics technique, such as by use of Self Excited Electron Plasma Resonance Spectroscopy (SEERS), a Langmuir probe or other suitable technique. It is believed that the inductively coupled coaxial coil element 110 configuration illustrated in FIG. 1 provides significant advantage in the control and generation of a high density plasma versus conventional plasma source configurations that include capacitively coupled and plasma source configurations.

Interposed between inductive coil elements 110 of the RF antenna and dielectric chamber lid 108 is a shielding electrode 118. Shielding electrode 118 may be alternately electrically floating or coupled to an electrical ground 119 via any suitable means for making and breaking an electrical connection, such as a switch 120 as illustrated in FIG. 1.

As shown, the bias power system 161 includes second impedance matching network 124, and biasing power source 126. Pedestal 104 is coupled, through a second impedance matching network 124, to a biasing power source 126. Biasing power source 126 is generally capable of producing an RF signal having a driven frequency that is within a range from 1 to 160 MHz and power between about 0 kW and about 3 kW, similar to RF power source 114. Biasing power source 126 is capable of producing between about 1W and 1 kilowatts (kW) at a frequency in a range from 2 to 160 MHz, with a frequency of 13.56 MHz or a frequency of 2 MHz. Optionally, biasing power source 126 may be a direct current (DC) or pulsed DC source. In some embodiments, an electrode that is coupled to the biasing power source 126 is disposed within the electrostatic chuck 105. The bias power system 161 provides a substrate voltage bias across the substrate 128 to facilitate the treatment of the deposited thin film. In one embodiment, the RF bias provides energetic ions having up to 2000 eV of ion energy.

As shown, the controller 146 includes central processing unit (CPU) 148, memory 150, and support circuits 152. Controller 146 may interface with RF power source 114, switch 120, detector 122, and biasing power source 126. Controller 146 may be any suitable type of general purpose computer processor that can be used in an industrial setting for controlling various chambers and sub-processors. Memory 150, or other computer-readable medium, for CPU 148 may be one or more of any readily available memory forms, such as random access memory (RAM), read only memory (ROM), a floppy disk, a hard disk, or any other form of digital storage, local or remote. Support circuits 152 may be coupled to CPU 148 in an effort to support the processor in a conventional manner. These circuits may include cache, power supplies, clock circuits, input/output (I/O) circuitry and subsystems, and the like. For some embodiments, the techniques disclosed herein for energizing and maintaining a plasma may be stored in memory 150 a software routine. The software routine may also be stored and/or executed by a second CPU (not shown) that is remotely located from the hardware being controlled by CPU 148. The controller 146 provides the processing chamber assembly 100 and the various subcomponents mentioned above with instructions for temperature control, bias voltage, gas flow rate, and the like.

One or more gaskets 166 are disposed between the chamber lid 108 and the chamber body 106, such that the one or more gaskets 166 are disposed between the chamber lid 108 and the upper chamber body 111. The one or more gaskets 166 assist in maintaining a seal between the chamber lid 108 and the chamber body 106 while also improving the electrical conductivity between the chamber lid 108 and the chamber body 106. The gaskets 166 are nickel plated copper gaskets or stainless steel gaskets. The gaskets 166 are nickel plated in order to reduce the particle contamination caused by the gaskets 166 during substrate processing. Using stainless steel gaskets similarly reduces the particle contamination within the process chamber. It has been found that utilizing low melting temperature metals as gaskets 166, such as lead, tin, or indium coated gaskets, creates ball or disk defects on the substrate. The low melting temperature metals, such as lead and tin are extracted by the hydrogen plasma during processing. Nickel plating the gaskets 166 has been found to dramatically reduce the particle contamination of the substrate caused by the gaskets 166. The nickel plating on the gaskets 166 has a thickness within the range of about 1 μm to about 3 mm, such as about 25 μm to about 100 μm, such as about 50 μm to about 80 μm. Similarly, replacing the low melting temperature metal gaskets with stainless steel gaskets has been shown to reduce the particle contamination caused by conventional gaskets.

One or more gaskets 168 are disposed between the upper chamber body 111 and the lower chamber body 113. The one or more gaskets 166 assist in maintaining a seal between the upper chamber body 111 and the lower chamber body 113, while also providing an electrically conductive path between the upper chamber body 111 and the lower chamber body 113. The gaskets 166 are nickel plated copper gaskets or stainless steel gaskets.

One or more gaskets 170 are disposed between the lower chamber body 113 and the pedestal 104. The one or more gaskets 170 assist in maintaining a seal between the lower chamber body 113 and the pedestal 104. The gaskets 170 additionally improve electrical connections between the lower chamber body 113 and the pedestal 104. The gaskets 170 are nickel plated copper gaskets or stainless steel gaskets. In some embodiments, the gaskets 170 may be disposed between the lower liner 107 and the pedestal 104.

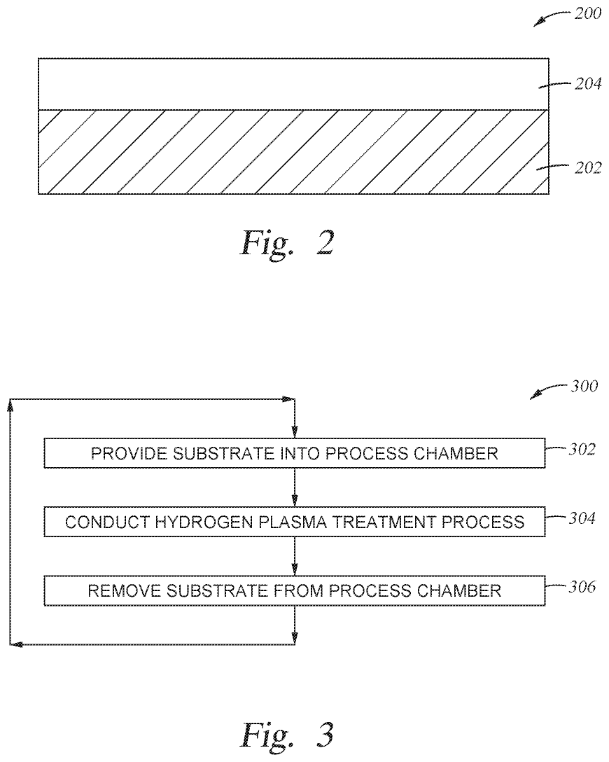

FIG. 2 is a schematic cross-sectional view of a portion of a ceramic coated chamber component 200. The ceramic coated chamber component 200 may be any one of the chamber lid 108, the upper liner 109, the lower liner 107, the liner door 156, the pedestal 104, and the electrostatic chuck 105. The ceramic coated chamber component 200 includes a component 202 and a ceramic coating 204. The component 202 is any one of the chamber lid 108, the upper liner 109, the lower liner 107, the liner door 156, the pedestal 104, or the electrostatic chuck 105.

The component 202 may include multiple layers, such as a base copper layer coated with a lead or tin layer. The copper layer may be the primary component of each of the chamber components 200. The base lead or tin layer may be a layer between the primary component and the ceramic coating 204.

In some embodiments, the component 202 is a single material and does not include multiple layers. The single material may comprises any one of aluminum oxide, quartz, or copper. The component 202 has the ceramic coating 204 disposed directly thereon.

The ceramic coating 204 is a coating deposited on top of the component 202 to minimize the contamination particles deposited on a substrate, such as the substrate 128, within the process chamber assembly 100. The ceramic coating 204 may comprise a Y₂O₃—ZrO₂ solid solution. The Y₂O₃—ZrO₂ solid solution is a solid phase solution of Y₂O₃ and ZrO₂ compounds. The Y₂O₃ and ZrO₂ compounds are in a single homogeneous phase. The Y₂O₃—ZrO₂ solid solution is about 20 molecular percent to about 50 molecular percent ZrO₂. In some embodiments, the Y₂O₃—ZrO₂ solid solution is about 25 molecular percent to about 45 molecular percent ZrO₂, such as about 30 molecular percent to about 40 molecular percent ZrO₂. In some embodiments, there is a small amount of Y₂O liquid residue along with the Y₂O₃—ZrO₂ single phase.

The ceramic coating 204 may have a coating of about 2% to about 10% (e.g., less than approximately 5% in one embodiment) porosity. In some embodiments, the porosity of the ceramic coating 204 is less than about 3%, such as less than 2%, such as less than 1%. The ceramic coating 204 has a hardness of approximately 3-8 gigapascals (GPa) (e.g., greater than approximately 4 GPa in one embodiment), and a thermal shock resistance of approximately 8-20 megapascals (MPa) (e.g., greater than approximately 10 MPa in one embodiment). Additionally, the ceramic coating may have an adhesion strength of approximately 4-20 MPa (e.g., greater than approximately 14 MPa in one embodiment). Adhesion strength may be determined by applying a force (e.g., measured in megapascals) to the ceramic coating until the ceramic coating peels off from the ceramic substrate.

The ceramic coating 204 is formed by spraying or growing the ceramic coating on the ceramic substrate. The component 202 is formed by a sintering process or machining. In embodiments in which the ceramic coating 204 is spray coated, the ceramic coating 204 is a spray coated yttrium zirconium oxide. The spray coated yttrium zirconium oxide includes a thickness of about 10 μm to about 500 μm, such as about 15 μm to about 400 μm, such as about 20 μm to about 300 μm, such as about 20 μm to about 250 μm. Coating components with the spray coated yttrium zirconium oxide enables the thickness of the ceramic coating 204 to be greater than a physical vapor deposition (PVD) yttrium zirconium oxide coating deposited using other ceramic deposition processes and prevents cracking of the ceramic coating 204 at thicknesses greater than about 15 μm. The increased thickness prevents metal contaminants from passing through the ceramic coating 204 during processing and decreases the frequency of maintenance. The spray coated yttrium zirconium oxide is easily applied to large components 202, such as the upper liner 109, the lower liner 107, the liner door 156, and the pedestal 104. The spray coated yttrium zirconium oxide is applied using thermal spraying techniques and/or plasma spraying techniques. Thermal spraying techniques and plasma spraying techniques may melt materials (e.g., ceramic powders) and spray the melted materials onto the component 202. The ceramic coating may have structural properties that are significantly different from those of bulk ceramic materials (e.g., such as the ceramic substrate).

Alternatively, the ceramic coating 204 is formed by depositing the ceramic coating on the ceramic substrate through a PVD coating process. In embodiments in which the ceramic coating 204 is deposited using a PVD coating process, the ceramic coating 204 is a PVD coated yttrium zirconium oxide. The PVD coated yttrium zirconium oxide includes a thickness of less than about 15 μm, such as less than about 10 μm, such as about 0.5 μm to about 10 μm, such as about 0.75 μm to about 7.5 μm, such as about 1 μm to about 5 μm. The PVD coated yttrium zirconium oxide is applied to smaller components 202, such as the chamber lid 108. The PVD coated yttrium zirconium oxide has a lower porosity than the spray coated yttrium zirconium oxide. The spray coated zirconium oxide has a porosity of about 0.5% to about 5%, such as about 1% to about 4%, such as about 2% to about 3%. The PVD coated yttrium zirconium oxide has a porosity of about 0% to about 1%, such as about 0% to about 0.5%, such as about 0% to about 0.25%.

The PVD coated yttrium zirconium oxide is a relatively thin coating layer. The PVD coating is advantageous for use on the chamber lid 108 because PVD coating is capable of withstanding the effects of hydrogen plasma adjacent to the chamber lid 108. The PVD coating is more easily deposited on flat surfaces, such as the bottom surface of the chamber lid 108. The PVD coating of the second yttrium zirconium oxide coating is more uniform and has a higher density than the spray on coating of the spray coated yttrium zirconium oxide. The PVD coating process may alternatively be a CVD or an ALD coating process. The CVD and ALD processes may produce similar results as the PVD coating, such as a similar porosity and thickness.

In some embodiments, a laminated or sintered yttrium zirconium oxide layer is formed on a substrate, such as on the gas nozzle 131, the plasma screen ring 129, the chamber lid 108, and/or the fastener cover 162. The laminated or sintered yttrium zirconium oxide layer may be formed using two different deposition techniques and may have varying physical properties. In some embodiments, the laminated or sintered yttrium zirconium oxide layer is formed by the deposition of a PVD coated yttrium zirconium oxide layer on top of a spray coated yttrium zirconium oxide layer. The deposition of the PVD coated layer on top of the spray coated layer forms a laminated yttrium zirconium oxide layer. The laminated yttrium zirconium oxide layer is a layer formed by one or more successive depositions of the yttrium zirconium oxide via spray coating and PVD coating.

The spray coated yttrium zirconium oxide layer is formed on a substrate before forming a second yttrium zirconium oxide layer thereon. The spray coated yttrium zirconium oxide layer is similar to the spray coated yttrium zirconium oxide layer described herein. The spray coated yttrium zirconium oxide layer is a low stress layer, such that the spray coated yttrium zirconium oxide adheres well to the substrate with a low stress. A PVD coating, such as the PVD coated yttrium zirconium oxide is deposited on top of the spray coated yttrium zirconium oxide layer. The PVD coated yttrium zirconium oxide layer is a higher stress layer than the spray coated yttrium zirconium oxide layer when deposited on the substrate by itself. By depositing the PVD coated yttrium zirconium oxide layer on top of the spray coated yttrium zirconium oxide layer, the stress within the PVD coated yttrium zirconium oxide layer is reduced, such that the stress within the PVD coated yttrium zirconium oxide layer on top of the spray coated yttrium zirconium oxide layer is less than the higher stress layer of the spray coated yttrium zirconium oxide layer, as the spray coated yttrium zirconium oxide layer acts as a bridge layer. Depending upon the structure, porosity, and thickness of the spray coated and PVD coated yttrium zirconium oxide layers, the stress within the coating compared to the PVD coating by itself is reduced by about 10% to about 90%.

Another embodiment of the laminated yttrium zirconium oxide layer is a sintered yttrium zirconium oxide layer. The sintered yttrium zirconium oxide layer is formed on the chamber lid 108 in some embodiments. The sintered yttrium zirconium oxide layer has a porosity of almost zero, such that the sintered yttrium zirconium oxide layer approximates the characteristics of a yttrium zirconium oxide bulk ceramic material. In some embodiments, the porosity of the sintered yttrium zirconium oxide layer is less than about 0.2%, such as less than about 0.1%, such as less than about 0.05%, such as less than 0.01%. In some embodiments, the sintered yttrium zirconium oxide layer has a thickness of about 0.5 mm to about 10 mm, such as about 1 mm to about 5 mm, such as about 1 mm to about 3 mm. The sintered yttrium zirconium oxide layer is formed using a sintering process, in which yttrium zirconium oxide powder is compressed onto a surface of the chamber lid 108 to form the sintered yttrium zirconium oxide layer. The sintered yttrium zirconium oxide layer is considered a laminate layer as it is coated on the bulk ceramic substrate, such as a bulk ceramic chamber lid 108. Alternatively, a layering process similar to the repeated spray coating and PVD coating of yttrium zirconium oxide is performed. After the repeated layering of the spray coated and PVD coated yttrium zirconium oxide, the layers may then be pressurized and heated to change the final layer structure and densify the structure to that similar to the sintered yttrium zirconium oxide layer.

The sintered yttrium zirconium oxide layer is thicker than either of the spray coated yttrium zirconium oxide layer or the PVD coated yttrium zirconium oxide layer. The sintered yttrium zirconium oxide layer may be used as the ceramic coating 204 of some process chamber assembly 100 components, such as the chamber lid 108. Using either of the laminated yttrium zirconium oxide layer or the sintered yttrium zirconium oxide layer as the ceramic coating 204 of the chamber lid 108 drastically reduces contaminant particles being deposited on the substrate by the lid 108 compared to either of the spray coated or PVD coated yttrium zirconium oxide layers because the laminated or sintered yttrium zirconium oxide layer better withstands the high hydrogen plasma concentration adjacent to the chamber lid 108.

All of the spray coated, the PVD coated, the laminated, and the sintered yttrium zirconium oxide layers may be formed from the Y₂O₃—ZrO₂ solid solution. The Y₂O₃—ZrO₂ solid solution is a purified Y₂O₃—ZrO₂ solution. The Y₂O₃—ZrO₂ solid solution is purified before deposition as a coating to reduce the amount of lead, tin, indium, and other low melting point metals within the Y₂O₃—ZrO₂ solid solution. The Y₂O₃—ZrO₂ solid solution is purified at least once to obtain a concentration of 99% or more Y₂O₃ and ZrO₂, such as 99.5% or more Y₂O₃ and ZrO₂, such as 99.9% or more Y₂O₃ and ZrO₂, such as 99.99% or more Y₂O₃ and ZrO₂. In some embodiments, there is less than 0.2 nanograms/gram of tin and less than 15 nanograms/gram of lead within the Y₂O₃—ZrO₂ solid solution. In some embodiments, there is less than 0.2 nanograms/gram of tin and less than 0.1 nanograms/gram of lead within the Y₂O₃—ZrO₂ solid solution. In yet other embodiments, there is less than 0.1 nanograms/gram of tin and less than 0.15 nanograms/gram of lead within the Y₂O₃—ZrO₂ solid solution. The Y₂O₃—ZrO₂ solid solution may have less than 0.05 nanograms/gram of tin and less than 0.01 nanograms/gram of lead. The reduced concentrations of lead and tin correspondingly reduce substrate contamination.

In some embodiments, the components 202 do not have a ceramic coating 204. The components 202 may instead be ceramic components themselves. Components 202 which may be ceramic components include the gas nozzle 131, the plasma screen ring 129, the chamber lid 108, and the fastener cover 162. The components 202 which are bulk ceramic components may be aluminum oxide (Al₂O₃), Al₂O₃—Y₂O₃ components or yttrium zirconium oxide components. The yttrium zirconium oxide components are bulk ceramic components. The yttrium zirconium oxide components have similar characteristics as the laminated yttrium zirconium oxide coatings. The ceramic components have a porosity of less than about 0.2%, such as less than about 0.1%, such as less than about 0.05%, such as less than 0.01%. The ceramic components have a concentration of 99% or more Y₂O₃ and ZrO₂, such as 99.5% or more Y₂O₃ and ZrO₂, such as 99.9% or more Y₂O₃ and ZrO₂, such as 99.99% or more Y₂O₃ and ZrO₂. In some embodiments, which may be combined with other embodiments, there is less than 0.2 nanograms/gram of tin and less than 15 nanograms/gram of lead within the yttrium zirconium oxide ceramic component. In some embodiments, there is less than 0.2 nanograms/gram of tin and less than 0.1 nanograms/gram of lead within the yttrium zirconium oxide ceramic component. In yet other embodiments, there is less than 0.1 nanograms/gram of tin and less than 0.15 nanograms/gram of lead within the yttrium zirconium oxide ceramic component. The yttrium zirconium oxide ceramic component may have less than 0.05 nanograms/gram of tin and less than 0.01 nanograms/gram of lead.

The ceramic components are used in order to reduce contaminant particle deposition on the substrate. The ceramic components prevent the deposition of tin or lead particles and also reduce the amount of yttrium, zirconium, and silicon oxide (SiO₂) particles otherwise emitted by the components. In some embodiments, the chamber lid 108 is an aluminum oxide (Al₂O₃) bulk ceramic. In other embodiments, the chamber lid 108 is a bulk ceramic of Al₂O₃—Y₂O₃ ceramic composite. The chamber lid 108 is replaced with a bulk ceramic Al₂O₃ or Al₂O₃—Y₂O₃ to reduce the amount of SiO₂ particles deposited on the substrate. The Al₂O₃ or Al₂O₃—Y₂O₃ chamber lid may still have a ceramic coating, such as the ceramic coating 204, disposed thereon. The ceramic coating 204 may be any one of the coating types described herein, but the laminated yttrium zirconium oxide layer reduces the quantity of contamination particles deposited by the largest amount.

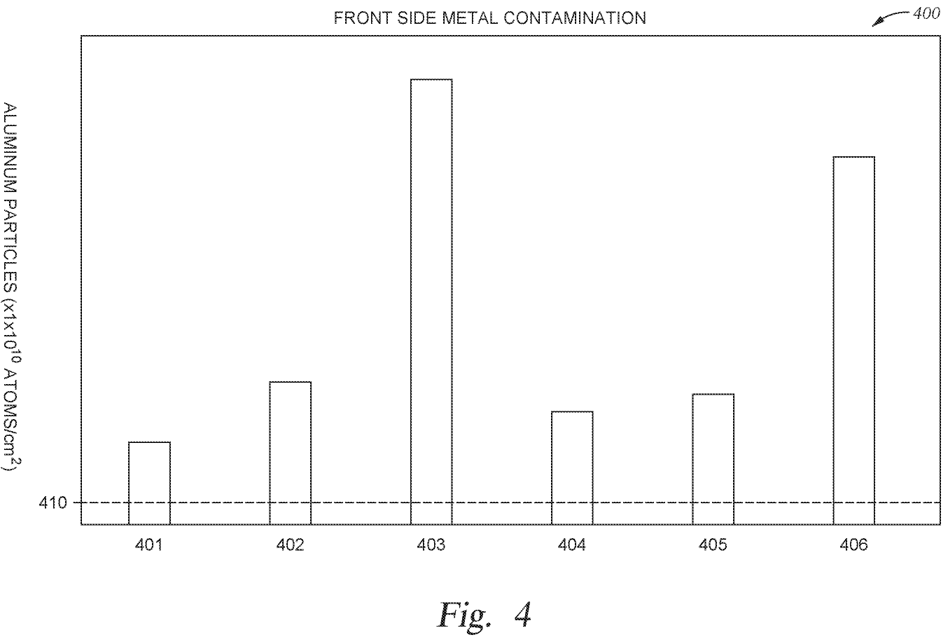

FIG. 3 is a method 300 of processing a substrate. The method includes a first operation 302 of providing a substrate into a process chamber, a second operation 304 of conducting a hydrogen plasma treatment, and a third operation 306 of removing the substrate from the process chamber. The method 300 can be looped continuously to process many substrates over time.

The first operation 302 of providing a substrate into a process chamber is performed by a robot arm. The robot arm may extend from a cluster tool into the process chamber, such as the processing chamber assembly 100 described herein. A substrate, such as the substrate 128, is deposited onto the top surface of the electrostatic chuck 105. The substrate may be a silicon substrate or may be a doped silicon substrate. In some embodiments, the substrate is has already gone through several other processing steps, such that the substrate has other features formed thereon not described herein. The substrate is moved into the process chamber to undergo a plasma treatment process, such as a hydrogen plasma treatment process.

The second operation 304 of conducting a hydrogen plasma treatment may include performing any type of substrate process in which a hydrogen plasma treatment is utilized. The hydrogen plasma treatment may be a hydrogen etch process, such that hydrogen free radicals and/or hydrogen ions are utilized to etch the surface of the substrate and any features formed thereon. In other embodiments, the hydrogen plasma treatment may be a cleaning process, such that the substrate is cleaned by the hydrogen plasma. The hydrogen plasma treatment may include carbon removal processes, chlorine/fluoride removal from metal treatments, oxygen removal treatments, high-k metal gate stack treatment, and mid-end-of-line contact treatment. Current chamber hardware is generally not compatible with hydrogen plasma treatments, such as those completed in the second operation 304. Current chamber hardware produces high amounts of metal contaminants and other contaminant particles. Using chamber components described herein drastically reduces the amount of metal and non-metal contaminant particles deposited on the substrate during hydrogen plasma treatment processes.

The third operation 306 of removing the substrate from the process chamber is performed after the completion of the hydrogen plasma treatment. Removing the substrate from the process chamber may be completed by a robot arm similar to the robot arm used in the first operation 302. The substrate may be removed from process chamber and transferred into a transfer chamber of a cluster tool. The substrate may then undergo other processing steps on other processing chambers connected to the cluster tool.

After the completion of the third operation 306, another substrate may be provided into the process chamber and the method 300 is repeated. The method 300 may be repeated until maintenance is performed on the process chamber. Due to the use of yttrium zirconium oxide coatings and bulk ceramic parts throughout the process chamber, the method 300 is able to be performed a greater amount of times before maintenance is completed, compared to conventional processing chambers.

FIG. 4 is a chart 400 illustrating substrate particle contamination levels. The chart 400 is a bar graph showing aluminum particle concentrations on a substrate after a hydrogen plasma treatment process, similar to that completed in operation 304 of the method 300, within a process chamber, such as the process chamber assembly 100. In the hydrogen plasma treatment process utilized to obtain the data of chart 400, the process was performed at 450 degrees Celsius. 750 Watts were applied via the inductive coil element 110, the pressure was maintained at 50 mTorr, the plasma processing chamber 101 was filled with 5% H₂ and 95% Argon, and the process was performed for 90 seconds. The particles are shown in concentrations of 1×10¹⁰ atoms/cm². The aluminum particles are disposed on the front side of a substrate, such as the substrate 128.

The first contaminant source level 401, the second contaminant source level 402, the third contaminant source level 403, the fourth contaminant source level 404, the fifth contaminant source level 405, and the sixth contaminant source level 406 are each above the desired contaminant concentration threshold 410.

The desired contaminant concentration threshold 410 is less than 1×10¹⁰ atoms/cm². As shown in the chart 400, all of the first, second, third, fourth, fifth, and sixth contaminant sources 401, 402, 403, 404, 405, 406 are greater than the 1×10¹⁰ atoms/cm² threshold. The first, second, third, fourth, fifth, and sixth contaminant sources 401, 402, 403, 404, 405, 406 are non-ceramic or non-ceramic coated contamination sources within the chamber assembly 100. By utilizing the coatings and component compositions described herein, the desired contaminant concentration threshold 410 is met and the contaminants produced by each of the contaminant sources is reduced or eliminated entirely.

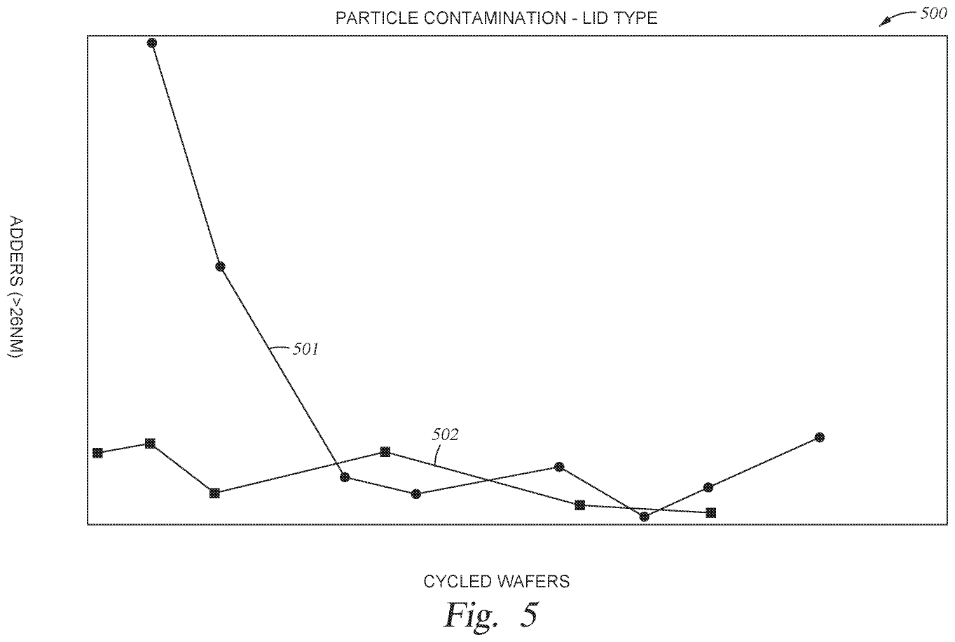

FIG. 5 is a graph 500 illustrating substrate particle contamination caused by the process chamber lid. The first trend line 501 illustrates the number of contaminant particle adders disposed on a substrate, such as the substrate 128, within the process chamber, such as the plasma processing chamber 101, when a quartz lid with a PVD yttrium zirconium oxide coating is utilized. The second trend line 502 illustrates the number of contaminant particle adders disposed on a substrate, such as the substrate 128, within the process chamber, such as the plasma processing chamber 101, when an aluminum oxide chamber lid with a yttrium oxide (Y₂O₃) coating utilized thereon.

The aluminum oxide chamber lid with yttrium oxide coating provides lower particle contamination more consistently over a larger quantity of wafer processing cycles. The utilization of a laminated or sintered yttrium zirconium oxide coating enables the quartz lid to have similar or better results than the aluminum oxide chamber lid with the yttrium oxide coating, such that there would be less particle contamination of the substrate.

Embodiments described herein may be altered to decrease particle contamination on the substrate, decrease total cost, or improve ease of application of coatings on chamber components. In one exemplary embodiment, the process chamber assembly 100 includes a chamber lid 108 made of quartz, a gas nozzle 131 made of a bulk yttrium zirconium oxide ceramic, a liner door 156 coated with a spray coated yttrium zirconium oxide layer, a plasma screen ring 129 made of a bulk yttrium zirconium oxide ceramic, an upper liner 109 coated with a spray coated yttrium zirconium oxide layer, a lower liner 107 coated with a spray coated yttrium zirconium oxide layer, and fastener covers 162 made of a bulk yttrium zirconium oxide ceramic.

In another embodiment, the process chamber assembly 100 includes a chamber lid 108 made of aluminum oxide or Al₂O₃—Y₂O₃ bulk ceramic with a PVD coated yttrium zirconium oxide layer, a gas nozzle 131 made of a bulk yttrium zirconium oxide ceramic, a liner door 156 coated with a spray coated yttrium zirconium oxide layer, a plasma screen ring 129 made of a bulk yttrium zirconium oxide ceramic, an upper liner 109 coated with a spray coated yttrium zirconium oxide layer, a lower liner 107 coated with a spray coated yttrium zirconium oxide layer, and fastener covers 162 made of a bulk yttrium zirconium oxide ceramic.

In another embodiment, the process chamber assembly 100 includes a chamber lid 108 made of aluminum oxide or Al₂O₃—Y₂O₃ ceramic composite with a laminated or sintered yttrium zirconium oxide coating, a gas nozzle 131 made of a bulk yttrium zirconium oxide ceramic, a liner door 156 coated with a spray coated yttrium zirconium oxide layer, a plasma screen ring 129 made of a bulk yttrium zirconium oxide ceramic, an upper liner 109 coated with a spray coated yttrium zirconium oxide layer, a lower liner 107 coated with a spray coated yttrium zirconium oxide layer, and fastener covers 162 made of a bulk yttrium zirconium oxide ceramic.

In another embodiment, the process chamber assembly 100 includes a chamber lid 108 made of aluminum oxide or Al₂O₃—Y₂O₃ ceramic composite with a yttrium oxide coating, a gas nozzle 131 made of a bulk yttrium zirconium oxide ceramic, a liner door 156 coated with a spray coated yttrium zirconium oxide layer, a plasma screen ring 129 made of a bulk yttrium zirconium oxide ceramic, an upper liner 109 coated with a spray coated yttrium zirconium oxide layer, a lower liner 107 coated with a spray coated yttrium zirconium oxide layer, and fastener covers 162 made of a bulk yttrium zirconium oxide ceramic.

In another embodiment, the process chamber assembly 100 includes a chamber lid 108 made of quartz with a laminated or sintered yttrium zirconium oxide coating, a gas nozzle 131 made of a bulk yttrium zirconium oxide ceramic, a liner door 156 coated with a spray coated yttrium zirconium oxide layer, a plasma screen ring 129 made of a bulk aluminum oxide ceramic, an upper liner 109 coated with a spray coated yttrium zirconium oxide layer, a lower liner 107 coated with a spray coated yttrium zirconium oxide layer, and fastener covers 162 made of a bulk yttrium zirconium oxide ceramic.

In another embodiment, the process chamber assembly 100 includes a chamber lid 108 made of aluminum oxide or Al₂O₃—Y₂O₃ ceramic composite with a PVD coated yttrium zirconium oxide layer, a gas nozzle 131 made of a bulk yttrium zirconium oxide ceramic, a liner door 156 coated with a spray coated yttrium zirconium oxide layer, a plasma screen ring 129 made of a bulk aluminum oxide ceramic, an upper liner 109 coated with a spray coated yttrium zirconium oxide layer, a lower liner 107 coated with a spray coated yttrium zirconium oxide layer, and fastener covers 162 made of a bulk yttrium zirconium oxide ceramic.

In another embodiment, the process chamber assembly 100 includes a chamber lid 108 made of aluminum oxide or Al₂O₃—Y₂O₃ ceramic composite with a laminated or sintered yttrium zirconium oxide coating, a gas nozzle 131 made of a bulk yttrium zirconium oxide ceramic, a liner door 156 coated with a spray coated yttrium zirconium oxide layer, a plasma screen ring 129 made of a bulk aluminum oxide ceramic, an upper liner 109 coated with a spray coated yttrium zirconium oxide layer, and a lower liner 107 coated with a spray coated yttrium zirconium oxide layer, and fastener covers 162 made of a bulk yttrium zirconium oxide ceramic.

In another embodiment, the process chamber assembly 100 includes a chamber lid 108 made of aluminum oxide or Al₂O₃—Y₂O₃ ceramic composite with a yttrium oxide coating, a gas nozzle 131 made of a bulk yttrium zirconium oxide ceramic, a liner door 156 coated with a spray coated yttrium zirconium oxide layer, a plasma screen ring 129 made of a bulk aluminum oxide ceramic, an upper liner 109 coated with a spray coated yttrium zirconium oxide layer, a lower liner 107 coated with a spray coated yttrium zirconium oxide layer, and fastener covers 162 made of a bulk yttrium zirconium oxide ceramic.

In some embodiments, the plasma screen ring 129 may comprise a plasma screen ring with a spray coated yttrium zirconium oxide layer. The spray coated yttrium zirconium oxide layer may be utilized on the plasma screen ring 129 in any of the embodiments described herein. Additionally, the spray coated yttrium zirconium oxide may be utilized on plasma screen rings 129 not described herein, such as quartz plasma screen rings.

In yet other embodiments, any of the gas nozzle 131, the plasma screen ring 129, the chamber lid 108, or the fastener covers 162 may be made from a bulk aluminum oxide ceramic. Additionally, any of the gas nozzle 131, the plasma screen ring 129, the chamber lid 108, or the fastener covers 162 described in the embodiments herein may include a first yttrium zirconium oxide coating.

While the foregoing is directed to embodiments of the present disclosure, other and further embodiments of the disclosure may be devised without departing from the basic scope thereof, and the scope thereof is determined by the claims that follow.

What is claimed is:

1. An apparatus for substrate processing comprising:
a chamber body;
a lower liner disposed within the chamber body;
an upper liner disposed on top of the lower liner and within the chamber body;
a liner door disposed through the upper liner and the chamber body, wherein each of the lower liner, the upper liner, and the liner door further comprise a spray coated yttrium zirconium oxide layer disposed thereon;
a chamber lid disposed on top of the chamber body; and
a gas nozzle disposed through the chamber lid, wherein the gas nozzle further comprises a bulk ceramic gas nozzle.

2. The apparatus of claim 1, further comprising a plasma screen ring disposed on top of the electrostatic chuck, wherein the plasma screen ring is a bulk ceramic plasma screen ring.

3. The apparatus of claim 1, further comprising one or more fasteners disposed through and securing the lower liner and the substrate support pedestal, each of the one or more fasteners having a bulk yttrium zirconium oxide ceramic fastener cover disposed thereon.

4. The apparatus of claim 1, wherein the chamber lid comprises an Al₂O₃ lid and a Y₂O₃ coating.

5. The apparatus of claim 1, wherein the chamber lid comprises an Al₂O₃—Y₂O₃ ceramic composite and a Y₂O₃ coating.

6. The apparatus of claim 1, wherein the chamber lid further comprises a quartz lid.

7. The apparatus of claim 1, wherein the chamber lid further comprises one of an aluminum oxide lid or an Al₂O₃—Y₂O₃ lid with a laminated or sintered yttrium zirconium oxide coating.

8. The apparatus of claim 1, wherein the yttrium zirconium oxide further comprises a Y₂O₃—ZrO₂ solid solution.

9. The apparatus of claim 1, wherein one or more gaskets are disposed between the lower chamber body and the upper chamber body.

10. The apparatus of claim 9, wherein one or more gaskets are disposed between the upper chamber body and the chamber lid.

11. The apparatus of claim 10, wherein one or more gaskets are disposed between the lower chamber body and the substrate support pedestal.

12. The apparatus of claim 11, wherein each of the one or more gaskets comprises a nickel plated gasket or a stainless steel gasket.

13. An apparatus for substrate processing comprising:
a chamber body;
a lower liner disposed within the chamber body;
an upper liner disposed on top of the lower liner and within the chamber body;
a liner door disposed through the upper liner and the chamber body, wherein each of the lower liner, the upper liner, and the liner door further comprise a spray coated yttrium zirconium oxide layer disposed thereon, wherein the yttrium zirconium oxide further comprises a Y₂O₃—ZrO₂ solid solution;
a chamber lid disposed on top of the upper liner;
a gas nozzle disposed through the chamber lid, wherein the gas nozzle further comprises a bulk ceramic gas nozzle; and
one or more nickel plated or stainless steel gaskets disposed between the lower liner and the upper liner, the upper liner and the chamber lid, and the lower liner and the substrate support pedestal.

14. The apparatus of claim 13, wherein the thickness of each of the spray coated yttrium zirconium oxide layer is about 25 microns to about 300 microns.

15. The apparatus of claim 13, wherein the chamber lid further comprises an aluminum oxide lid and a PVD coated yttrium zirconium oxide layer, wherein the PVD coated yttrium zirconium oxide layer has a thickness of about 0.5 microns to about 10 microns.

16. The apparatus of claim 13, wherein the spray coated yttrium zirconium oxide layer is a purified yttrium zirconium oxide coating with a concentration of 99% or more Y₂O₃ and ZrO₂.

17. The apparatus of claim 16, wherein the bulk ceramic gas nozzle is a yttrium zirconium oxide ceramic gas nozzle with a porosity of equal to or less than about 0.2%.

18. The apparatus of claim 13, further comprising a plasma screen ring disposed on top of the electrostatic chuck, wherein the plasma screen ring is a bulk yttrium zirconium oxide ceramic or an alumina ring coated by Y₂O₃—ZrO₂.

19. An apparatus for substrate processing comprising:
a chamber body:
a lower liner disposed within the chamber body;
an upper liner disposed on top of the lower liner and within the chamber body;
a liner door disposed through the upper liner and the chamber body, wherein each of the lower liner, the upper liner, and the liner door further comprise a spray coated yttrium zirconium oxide layer disposed thereon;
a chamber lid disposed on top of the upper liner;
a gas nozzle disposed through the chamber lid, wherein the gas nozzle further comprises a bulk ceramic gas nozzle;
an induction coil disposed above the chamber lid; and
a shielding electrode disposed between the induction coil and the chamber lid, wherein
the thickness of the spray coated yttrium zirconium oxide layer is about 25 microns to about 300 microns and the spray coated yttrium zirconium oxide layer is a purified yttrium zirconium oxide coating with a concentration of 99% or more Y₂O₃ and ZrO₂.

20. The apparatus of claim 19, wherein the chamber lid further comprises an aluminum oxide lid and a PVD coated yttrium zirconium oxide coating.
